(19) United States
(12) Patent Application Publication
(10) Pub. No.: US 2022/0255532 A1
(43) Pub. Date: Aug. 11, 2022

(54) DUPLEXER WITH HIGH ISOLATION AND HIGH STEEPNESS ON LOW-FREQUENCY SIDE OF RECEIVING BAND

(71) Applicant: Chengdu Pinnacle Microwave Co., Ltd., Chengdu (CN)

(72) Inventors: Yuandan DONG, Chengdu (CN); Mengjuan ZHAO, Chengdu (CN); Tao YANG, Chengdu (CN); Zenghong MA, Chengdu (CN)

(21) Appl. No.: 17/547,459

(22) Filed: Dec. 10, 2021

(30) Foreign Application Priority Data
Feb. 5, 2021 (CN) 202110159195.4

(51) Int. Cl. H03H 9/64; H03H 9/72

(52) U.S. Cl. CPC H03H 9/6483; H03H 9/725

(57) ABSTRACT

A duplexer is provided with high isolation and high steepness on low-frequency side of a receiving band, including an antenna terminal, a transmitting terminal and a receiving terminal arranged on a piezoelectric substrate, where a transmitting filter is connected between the antenna terminal and the transmitting terminal; a receiving filter, with a series arm and multiple parallel arms connected to the series arm, is connected between the antenna terminal and the receiving terminal; the series arm is provided with a DMS filter and multiple series arm resonators; each parallel arm is provided with a parallel arm resonator; and the DMS filter is in common ground connection with all the parallel arm resonators of the receiving filter. The duplexer can better improve the passband isolation and increase the steepness on the low-frequency side of the high passband without additional components and structural complexity, thereby improving performance and providing high practicability.

### CROSS REFERENCE TO RELATED APPLICATION(S)

This patent application claims the benefit and priority of Chinese Patent Application No. 202110159195.4 filed on Feb. 5, 2021, and the disclosure of which is incorporated by reference herein in its entirety as part of the present application.

### TECHNICAL FIELD

The present disclosure relates to the technical field of microwave communication, in particular to a duplexer with high isolation and high steepness on a low-frequency side of a receiving band.

### BACKGROUND ART

A duplexer is a special bi-directional three-terminal filter. The duplexer not only needs to couple weak receiving signals in, but also needs to feed higher transmitting power to an antenna, and requires the two to implement their functions without mutual effect, respectively. With continually increasing requirements for a high-performance system in a radio frequency communication system, the performance of the duplexer plays a crucial role in the performance of the entire communication system. The isolation of the duplexer on a transceiver end determines the degree of interference between signals. The improvement of the isolation can not only greatly reduce the interference, but also reduce the use of peripheral components. The duplexer generally consists of two sets of band-pass filters with different frequencies, namely a transmitting passband filter and a receiving passband filter. Therefore, the performance of the transmitting passband filter and the receiving passband filter has significant effect on the performance of the duplexer. The low insertion loss inside the band, high stopband suppression, and passband edge steepness, etc., are the primary performance indexes which need to be considered. In some existing duplexer designs, the transmitting passband filter and the receiving passband filter are both ladder-type filters, or the receiving passband filter is constructed by a double-mode acoustic surface wave (Double-mode SAW, hereinafter referred to as DMS) structure and ladder-type structures together. The ladder-type filter has a plurality of parallel arm resonators, where the parallel arms are connected to a ground electrode of a ground potential, and the ground electrode is easily affected by parasitic inductance, resulting in a large difference between the resonance frequency and the anti-resonance frequency of the parallel arms, which deteriorates the steepness on the low-frequency side of the receiving passband, and adversely affects the isolation of the duplexer. Therefore, for this type of duplexer, how to obtain high steepness on the low-frequency transition band of the receiving passband filter and improve the isolation of the duplexer has become a problem to be solved.

### SUMMARY

The present disclosure aims to solve the above-mentioned problems and provide a novel duplexer that can improve the steepness and isolation on the low-frequency side of a receiving band.

The objective of the present disclosure is implemented by providing a duplexer with high isolation and high steepness on the low-frequency side of the receiving band, including an antenna terminal, a transmitting terminal and a receiving terminal arranged on a piezoelectric substrate, where a transmitting filter is connected between the antenna terminal and the transmitting terminal, a receiving filter is connected between the antenna terminal and the receiving terminal, the receiving filter has a series arm and a plurality of parallel arms connected to the series arm, the series arm is provided with a double-mode SAW (DMS) filter and a plurality of series arm resonators, each parallel arm is provided with a parallel arm resonator; and the DMS filter is in common ground connection with all the parallel arm resonators of the receiving filter.

Preferably, ground electrodes of all interdigital transducers (IDTs) in the DMS filter are in common ground connection with all the parallel arm resonators of the receiving filter.

Preferably, an input end of the DMS filter is connected to one end of a series arm resonator S1, the other end of the series arm resonator S1 is connected to the antenna terminal, an output end of the DMS filter is connected to one end of a series arm resonator S2, the other end of the series arm resonator S2 is connected to the receiving terminal, a parallel arm resonator P1 is connected between the series arm resonator S1 and the DMS filter, and a parallel arm resonator P2 is connected between the series arm resonator S2 and the DMS filter.

Preferably, the resonance frequency of the parallel arm resonator P1 is higher than that of the parallel arm resonator P2.

Preferably, the static capacitance of the parallel arm resonator P1 is smaller than that of the parallel arm resonator P2.

Preferably, the DMS filter is a fifth-order filter.

Preferably, the duplexer has a transmitting frequency band of 699 MHz-716 MHz, and a receiving frequency band of 729 MHz-746 MHz.

Preferably, the transmitting filter includes series arm resonators S3, S4, S5, S6 and S7 connected in series sequentially, where one end of the series arm resonator S3 is connected to the transmitting terminal, one end of the series arm resonator S7 is connected to the antenna terminal, a parallel arm resonator P3 is connected between the series arm resonators S4 and S5, a parallel arm resonator P4 is connected between the series arm resonators S5 and S6, a parallel arm resonator P5 is connected between the series arm resonates S6 and S7, and the parallel arm resonators P3, P4 and P5 are in common ground connection.

Preferably, the resonant frequencies of the series arm resonators S3 and S4 are different.

The present disclosure has the following beneficial technical effects:

The duplexer provided can better improve the passband isolation and increase the steepness on the low-frequency side of the receiving band without adding additional components and structural complexity, and obtain better out-of-band suppression performance at the same time.

### BRIEF DESCRIPTION OF THE DRAWINGS

FIG. 1 is a schematic circuit structure diagram of a duplexer of Embodiment 1 of the present disclosure.

FIG. 2 is a schematic circuit principle diagram of the duplexer of Embodiment 1 of the present disclosure.

FIG. 3 is a schematic circuit structure diagram of a duplexer of Comparative example 1.

FIG. 4 is a schematic circuit principle diagram of the duplexer of Comparative example 1.

FIG. 5 is a comparison diagram of S-parameter attenuation characteristic curves of receiving filters in Embodiment 1 of the present disclosure and Comparative example 1.

FIG. 6 is a comparison diagram of S-parameter isolation characteristic curves of the receiving filters in Embodiment 1 of the present disclosure and Comparative example 1.

FIG. 7 is a schematic circuit structure diagram of a duplexer of Comparative example 2.

FIG. 8 is a schematic circuit principle diagram of a duplexer of Comparative example 2.

FIG. 9 is a comparison diagram of S-parameter attenuation characteristic curves of receiving filters in Embodiment 1 of the present disclosure and Comparative example 2.

FIG. 10 is a comparison diagram of S-parameter isolation characteristic curves of the receiving filters in Embodiment 1 of the present disclosure and Comparative example 2.

The numerals in the drawings are as follows:
1—antenna terminal, 2—transmitting terminal, 3—receiving terminal, 4—first ground terminal, 5—second ground terminal, 6—third ground terminal, and 7—fourth ground terminal.

### DETAILED DESCRIPTION OF THE EMBODIMENTS

The duplexer of the present disclosure is described in detail below with reference to the accompanying drawings and embodiments. It should be noted that the implementation of the present disclosure is not limited to the specific embodiments provided.

The embodiment of the present disclosure provides a duplexer with high isolation and high steepness on a low-frequency side of a receiving band, including an antenna terminal, a transmitting terminal and a receiving terminal arranged on a piezoelectric substrate. A transmitting filter is connected between the antenna terminal and the transmitting terminal. A receiving filter is connected between the antenna terminal and the receiving terminal. The receiving filter has a series arm and a plurality of parallel arms connected to the series arm. The series arm is provided with a double-mode SAW (DMS) filter and a plurality of series arm resonators. Each parallel arm is provided with a parallel arm resonator. The DMS filter is in common ground connection with at least one parallel arm resonator. It is appreciated that the basic idea of the duplexer provided is to enable the DMS filter to be in common ground connection with at least one parallel arm resonator, which greatly reduces the bad influence of the parasitic inductance on the performance of the receiving filter, thereby improving the performance of the duplexer. As a better option, the DMS filter may be in common ground connection with all parallel arm resonators.

It is appreciated that the DMS filter can generally be configured as a multi-order longitudinally coupled resonator-type acoustic surface wave filter, and the order of the DMS filter depends on the quantity of interdigital transducers (IDTs). As an optional implementation, ground electrodes of all odd-numbered IDTs or all even-numbered IDTs of the DMS filter may be connected together, and are then in common ground connection with all parallel arm resonators. As the best option, it is recommended to connect the ground electrodes of all IDTs of the DMS filter together, and then enable them to be in common ground with all parallel arm resonators.

The duplexer designed in the present disclosure is particularly suitable to operate at a frequency band Band 12. The duplexer has a transmitting frequency band of 699 MHz-716 MHz, and a receiving frequency band of 729 MHz-746 MHz. For this operating frequency band, three types of duplexers with different structures are provided below. Embodiment 1 is more preferable. It should be noted that Comparative example 1, as well as Comparative example 2, also provides improvements to the existing duplexer, and the comparative examples are just terms relative to Embodiment 1.

### Embodiment 1

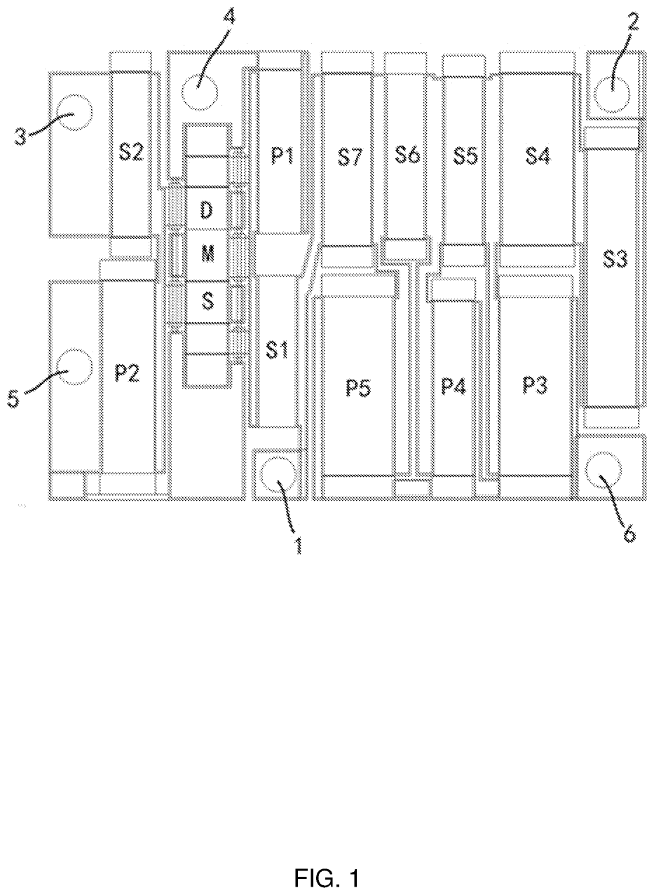

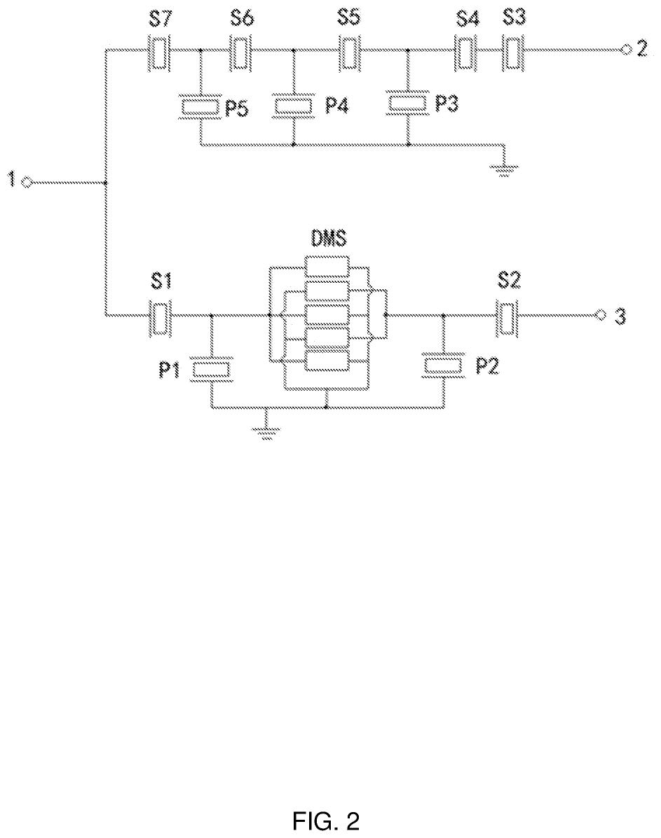

FIG. 1 and FIG. 2 respectively show a schematic circuit structure diagram and a circuit principle diagram of a duplexer of this embodiment. The duplexer of this embodiment includes an antenna terminal 1, a transmitting terminal 2 and a receiving terminal 3 arranged on a piezoelectric substrate. A transmitting filter is connected between the antenna terminal 1 and the transmitting terminal. A receiving filter is connected between the antenna terminal 1 and the receiving terminal 3. The receiving filter has a series arm and a plurality of parallel arms connected to the series arm. A series arm resonator S1, a DMS filter and a series arm resonator S2 are arranged on the series arm in sequence. One end of the series arm resonator S1 is connected to the antenna terminal 1, the other end of the series arm resonator S1 is connected to an input signal end of the DMS filter, an output signal end of the DMS filter is connected to one end of the series arm resonator S2, and the other end of the series arm resonator S2 is connected to the receiving terminal 3. A parallel arm resonator P1 is connected between the series arm resonator S1 and the DMS filter, and a parallel arm resonator P2 is connected between the series arm resonator S2 and the DMS filter. The ground electrodes of all IDTs of the DMS filter are connected together, and are then in common ground connection with a first ground terminal 4 together with the parallel arm resonator P1. The parallel arm resonator P2 is connected to a second ground terminal 5, and the first ground terminal 4 is connected to the second ground terminal 5. Therefore, a common ground connection of the DMS filter, the parallel arm resonator P1 and the parallel arm resonator P2 is formed. Further, the transmitting filter includes series arm resonators S3, S4, S5, S6 and S7 connected in series sequentially. One end of the series arm resonator S3 is connected to the transmitting terminal 2. One end of the series arm resonator S7 is connected to the antenna terminal 1. A parallel arm resonator P3 is connected between the series arm resonators S4 and S5. A parallel arm resonator P4 is connected between the series arm resonators S5 and S6. A parallel arm resonator P5 is connected between the series arm resonates S6 and S7. The parallel arm resonators P3, P4 and P5 are commonly connected to a third ground terminal 6.

As a preferred improvement, the resonance frequency of the parallel arm resonator P1 is configured to be higher than that of the parallel arm resonator P2. For reference, the specific resonance frequencies set in this embodiment are respectively as follows: the resonance frequency of the parallel arm resonator P1 is 718 MHz, and the resonance frequency of the parallel arm resonator P2 is 713 MHz. It should be noted that in a structure of the receiving filter, a difference between the resonance frequency and the anti-resonance frequency of the parallel arm resonator P1, as well as the parallel arm resonator P2, can affect the steepness on the low-frequency side of the receiving band. The smaller the difference between the resonance frequency and the anti-resonance frequency, the higher the steepness on the low-frequency side of the receiving band. Moreover, since the resonance frequency of the parallel arm resonator P1 of the receiving filter is close to the high-frequency band of the passband of the transmitting filter, the parallel arm resonator P1 has a greater influence on the steepness on the low-frequency side of the receiving band. Therefore, the arrangement above can promote the increase in the steepness on the low-frequency side of the passband of the receiving filter.

As a preferred improvement, static capacitance of the parallel arm resonator P1 is smaller than that of the parallel arm resonator P2. It is appreciated that the smaller the capacitance of the parallel arm resonator P1, the smaller the current from the parallel arm resonator P1 to the ground terminal, which can prevent the passband loss of the receiving filter from becoming worse due to current loss. For reference, the capacitance values in this embodiment are specifically set as follows: the static capacitance of the parallel arm resonator P1 is 3.62 pf, and the static capacitance of the parallel arm resonator P2 is 5.1 pf.

As a preference, in this embodiment, the DMS filter is configured as a fifth-order filter. It is appreciated that the DMS filter may be configured as a filter with a seventh order or a ninth order structure according to actual duplexer design requirements.

As a preference, the resonance frequencies of the series arm resonators S3 and S4 are different, such that the power tolerance of the receiving passband can be improved. It is appreciated that the series arm resonators S3 and S4 are usually interdigital resonators. Specifically, the series arm resonators S3 and S4 may have different interdigital pairs and different aperture lengths.

### COMPARATIVE EXAMPLE 1

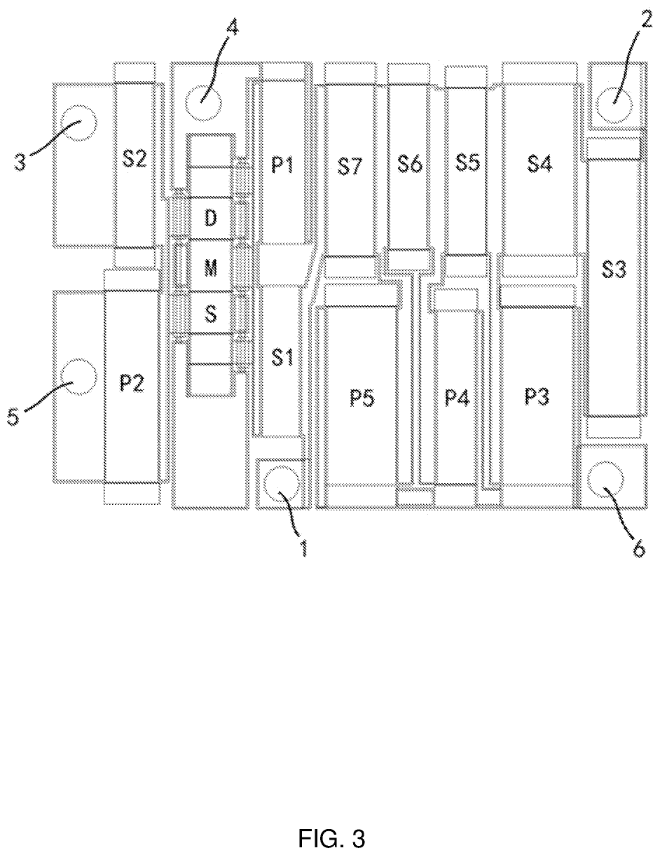

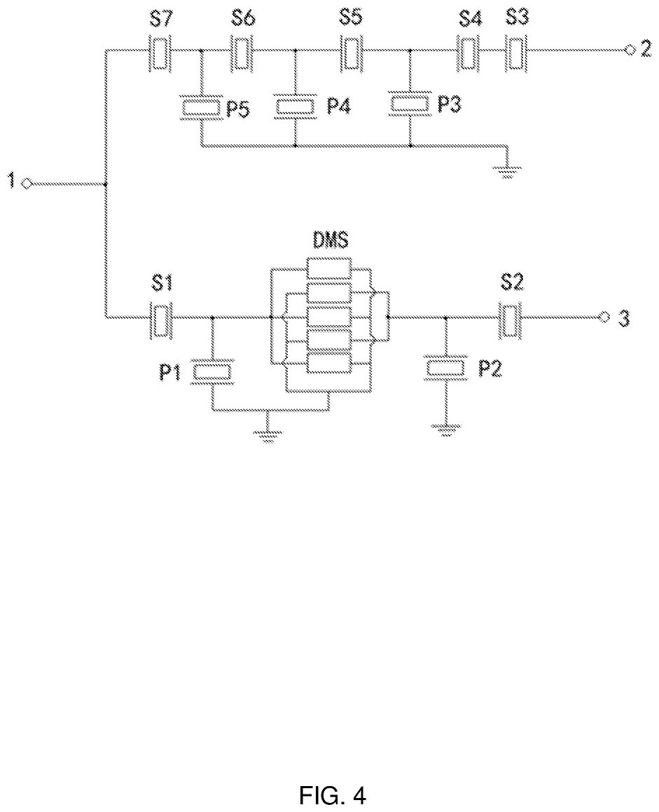

FIG. 3 and FIG. 4 respectively show a schematic circuit structure diagram and a circuit principle diagram of a duplexer of this embodiment. The duplexer of this embodiment has a circuit structure substantially the same as that of the duplexer of Embodiment 1. The difference only lies in that the ground electrodes of all IDTs of the DMS filter in the duplexer of this embodiment are connected together, and are then in common ground connection with the first ground terminal 4 together with the parallel arm resonator P1, and the parallel arm resonator P2 is separately grounded to the second ground terminal 5.

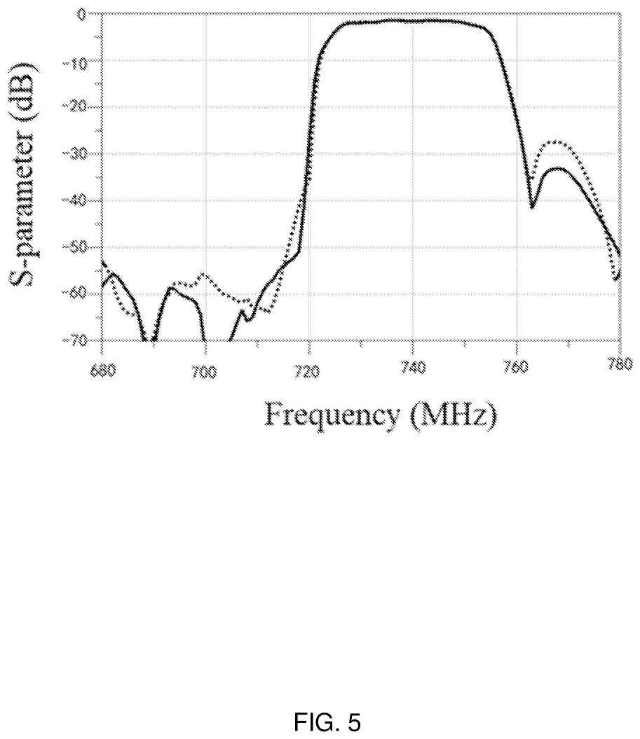

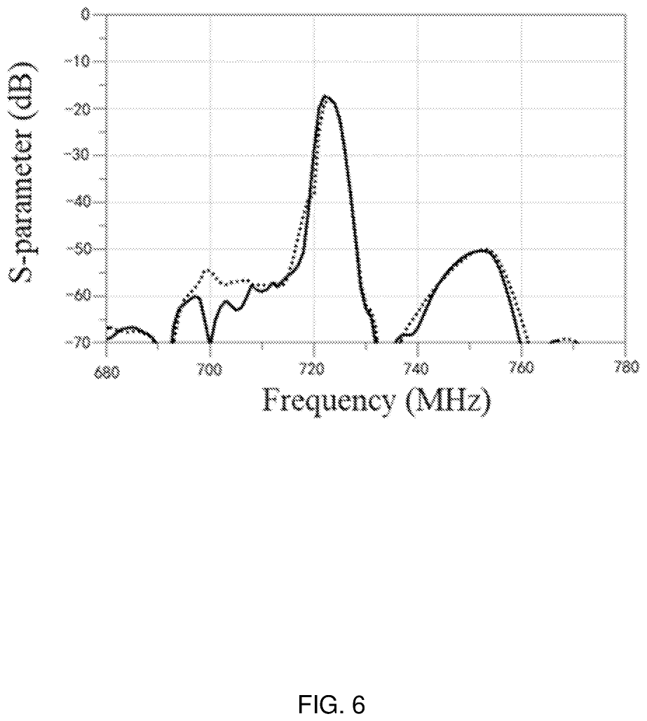

FIG. 5 shows a comparison diagram of S-parameter attenuation characteristic curves of receiving filters in Embodiment 1 of the present disclosure and Comparative example 1. In FIG. 5, the solid line represents an S-parameter attenuation characteristic curve of the receiving filter in Embodiment 1, and the dotted line represents an S-parameter attenuation characteristic curve of the receiving filter in Comparative example 1. It can be seen from FIG. 5 that for the attenuation of the low-frequency side of the passband of the receiving filter of Embodiment 1 from −3 dB to −50 dB, the frequency difference is 7 MHz, while for the attenuation of the low-frequency side of the passband of the receiving filter of Comparative example 1 from −3 dB to −50 dB, the frequency difference is 10 MHz. Therefore, the steepness on the low-frequency side of the passband of the receiving filter of Embodiment 1 is more excellent. FIG. 6 is a comparison diagram of the S-parameter isolation characteristic curves of receiving filter in Embodiment 1 of the present disclosure and Comparative example 1. In FIG. 6, the solid line represents an S-parameter isolation characteristic curve of the receiving filter in Embodiment 1, and the dotted line shows the S-parameter isolation characteristic curve of the receiving filter in Comparative example 1. It can be seen from FIG. 6 that the steepness on the low-frequency side of the passband of the receiving filter of Embodiment 1 is better, and at the same time the isolation level of the receiving filter of Embodiment 1 is more excellent in transmitting passband. It can be seen from FIGS. 5 and 6 that the duplexers of Embodiment 1 of the present disclosure and Comparative example 1 both have high steepness on the low-frequency side of the passband of the receiving filter, and high isolation of the receiving filter in the transmitting passband.

### COMPARATIVE EXAMPLE 2

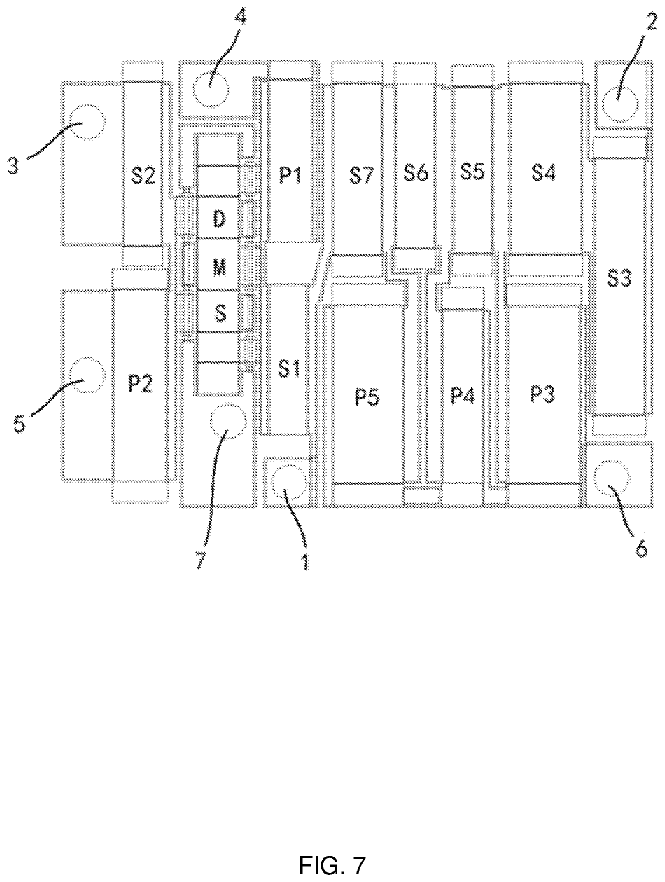

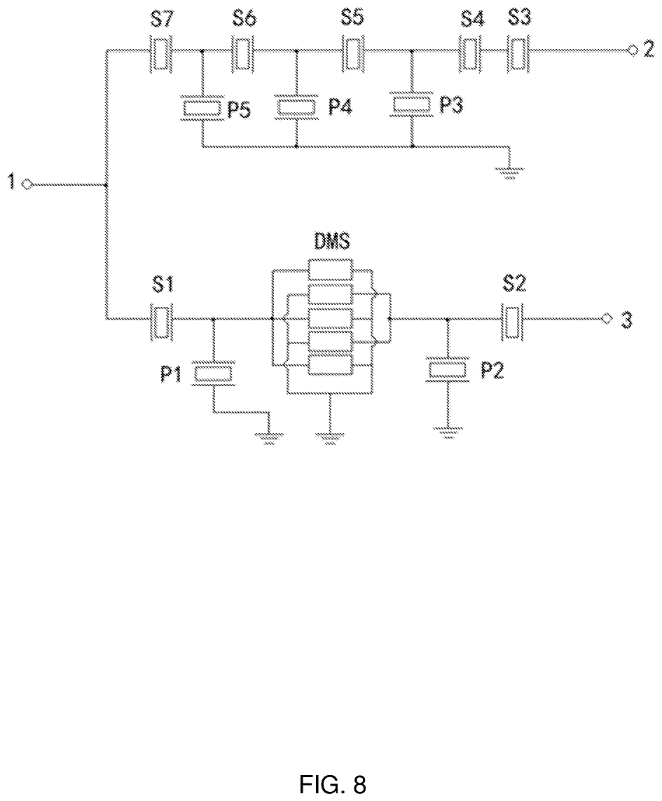

FIG. 7 and FIG. 8 respectively show a schematic circuit structure diagram and a circuit principle diagram of a duplexer of this embodiment. What the circuit structure of the duplexer of comparative example 2 differs from that of the duplexer of Embodiment 1 only lies in that the ground electrodes of all IDTs of the DMS filter in the duplexer of comparative example 2 are in common ground connection with a fourth terminal 7 together, the parallel arm resonator P1 is separately grounded to the first ground terminal 4, and the parallel arm resonator P2 is separately grounded to the second ground terminal 5.

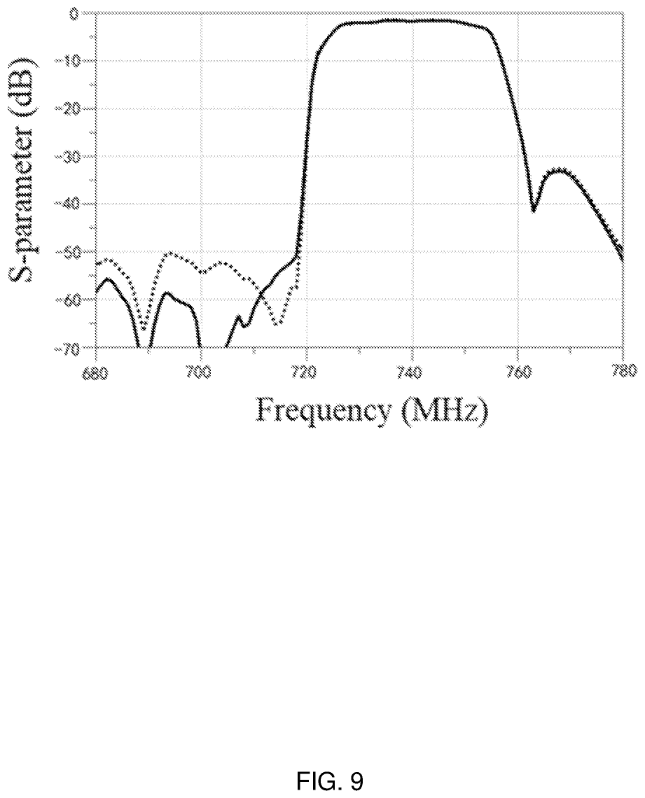

FIG. 9 shows a comparison diagram of S-parameter attenuation characteristic curves of receiving filters in Embodiment 1 of the present disclosure and Comparative example 2. In FIG. 9, the solid line represents an S-parameter attenuation characteristic curve of the receiving filter in Embodiment 1, and the dotted line represents an S-parameter attenuation characteristic curve of the receiving filter in Comparative example 2. It can be seen from FIG. 9 that although the steepness on the low-frequency side of the passband of the receiving filter of Embodiment 1 is close to the steepness on the low-frequency side of the passband of the receiving filter of Comparative example 2, the overall attenuation level of the receiving filter of Embodiment 1 in the transmitting passband is better than that of Comparative example 2. Analysis suggests that the mode that the ground terminal of the DMS filter in Comparative example 2 is separately grounded on the piezoelectric substrate cannot provide sufficient attenuation, which makes the isolation level of the receiving filter in the transmitting passband of Comparative example 2 worse than that of Embodiment 1.

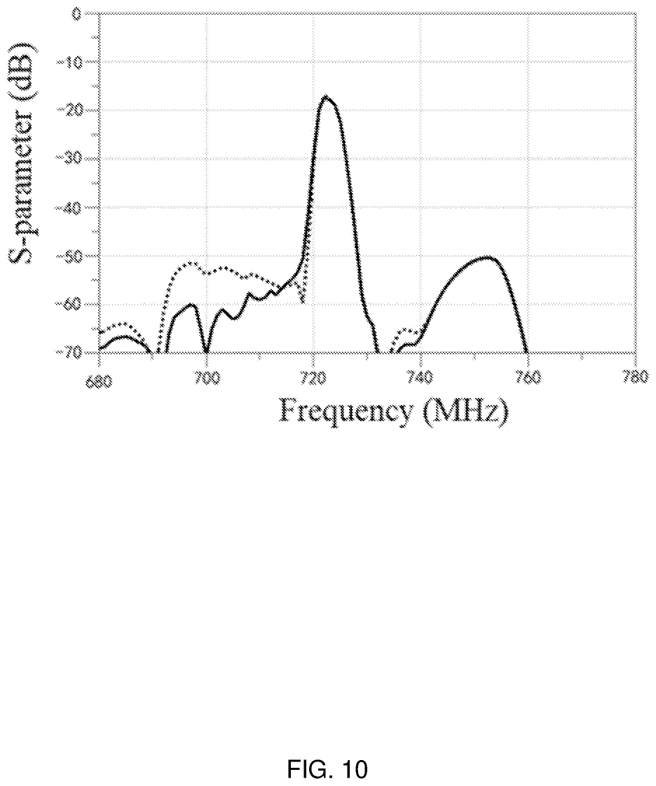

FIG. 10 shows a comparison diagram of S-parameter isolation characteristic curves of receiving filters in Embodiment 1 of the present disclosure and Comparative example 2. In FIG. 10, the solid line represents an S-parameter isolation characteristic curve of the receiving filter in Embodiment 1, and the dotted line represents an S-parameter isolation characteristic curve of the receiving filter in Comparative example 2. It can be seen from FIG. 10 that the isolation of the receiving filter of Embodiment 1 in the transmitting passband is better than that of Comparative example 2.

In the description of the embodiments of the present disclosure, it should be understood that the indicated orientation or positional relationship are based on the orientation or positional relationship shown in the drawings, and only used for describing the present disclosure and simplifying the description, rather than indicating or implying a device or a component specified must have a specific orientation, be constructed and operated in a specific orientation, and therefore cannot be understood as a limit to the present disclosure.

In the description of the embodiments of the present disclosure, the terms “first,” “second,” and “third” are only used for the purpose of description, and cannot be understood as indicating or implying relative importance or implicitly indicating the quantity of indicated technical features. Thus, the features defined with “first,” “second,” and “third” may explicitly or implicitly include one or more of these features. In the description of the present disclosure, unless otherwise specified, “a plurality of” means two or more.

In the description of the present disclosure, it should be noted that, unless otherwise specified and limited expressly, the terms “link,” and “connect” should be understood in a broad sense, for example, it may be a fixed connection, or a detachable connection, or an integral connection, it may be direct connection, or indirect connection through an intermediate medium, and it may be internal communication between two components. For a person of ordinary skill in the art, the specific meanings of the above-mentioned terms in the present disclosure can be understood in specific situations.

In the description of the embodiments of the present disclosure, the specific features, structures, materials or characteristics can be combined in any one or more embodiments or examples in a suitable manner.

In the description of the embodiments of the present disclosure, it should be understood that “-” and “˜” represent a range of two numerical values, and the range includes the endpoints. For example: “A-B” means a range greater than or equal to A and less than or equal to B. For example: “A˜B” means a range greater than or equal to A and less than or equal to B.

In the description of the embodiments of the present disclosure, the term “and/or” here is only used to describe an association relationship between associated objects, which can refer to three types of relationships. For example, A and/or B can refer to three cases, i.e., just A, both A and B, and just B. In addition, the character “/” here generally indicates that the associated objects before and after are in an “or” relationship.

Although the embodiments of the present disclosure have been shown and described, for a person of ordinary skill in the art, it will be understood that various changes, modifications, substitutions and variations can be made to these embodiments without departing from the principle and spirit of the present disclosure, and the scope of the present disclosure is defined by the appended claims and their equivalents.

What is claimed is:

1. A duplexer with high isolation and high steepness on a low-frequency side of a receiving band, comprising an antenna terminal, a transmitting terminal and a receiving terminal arranged on a piezoelectric substrate, wherein a transmitting filter is connected between the antenna terminal and the transmitting terminal, a receiving filter is connected between the antenna terminal and the receiving terminal, the receiving filter has a series arm and a plurality of parallel arms connected to the series arm, the series arm is provided with a double-mode SAW (DMS) filter and a plurality of series arm resonators, each parallel arm is provided with a parallel arm resonator; and the DMS filter is in common ground connection with all the parallel arm resonators of the receiving filter.

2. The duplexer according to claim 1, wherein ground electrodes of all interdigital transducers (IDTs) in the DMS filter are in common ground connection with all the parallel arm resonators.

3. The duplexer according to claim 2, wherein an input end of the DMS filter is connected to one end of a series arm resonator S1, the other end of the series arm resonator S1 is connected to the antenna terminal, an output end of the DMS filter is connected to one end of a series arm resonator S2, the other end of the series arm resonator S2 is connected to the receiving terminal, a parallel arm resonator P1 is connected between the series arm resonator S1 and the DMS filter, and a parallel arm resonator P2 is connected between the series arm resonator S2 and the DMS filter.

4. The duplexer according to claim 3, wherein the resonance frequency of the parallel arm resonator P1 is higher than that of the parallel arm resonator P2.

5. The duplexer according to claim 3, wherein static capacitance of the parallel arm resonator P1 is smaller than that of the parallel arm resonator P2.

6. The duplexer according to claim 3, wherein the DMS filter is a fifth-order filter.

7. The duplexer according to claim 1, wherein the duplexer has a transmitting frequency band of 699 MHz-716 MHz, and a receiving frequency band of 729 MHz-746 MHz.

8. The duplexer according to claim 3, wherein the transmitting filter comprises series arm resonators S3, S4, S5, S6 and S7 connected in series sequentially, one end of the series arm resonator S3 is connected to the transmitting terminal, one end of the series arm resonator S7 is connected to the antenna terminal, a parallel arm resonator P3 is connected between the series arm resonators S4 and S5, a parallel arm resonator P4 is connected between the series arm resonators S5 and S6, a parallel arm resonator P5 is connected between the series arm resonates S6 and S7, and the parallel arm resonators P3, P4 and P5 are in common ground connection.

9. The duplexer according to claim 8, wherein resonance frequencies of the series arm resonators S3 and S4 are different.
